(19) United States
(12) Patent Application Publication
(10) Pub. No.: US 2020/0006412 A1
(43) Pub. Date: Jan. 2, 2020

(54) METHODS AND APPARATUS FOR IMAGE SENSOR SEMICONDUCTORS

(71) Applicant: APPLIED MATERIALS, INC., Santa Clara, CA (US)

(72) Inventors: PHILIP HSIN-HUA LI, DANVILLE, CA (US); SESHADRI RAMASWAMI, SARATOGA, CA (US)

(21) Appl. No.: 16/442,789

(22) Filed: Jun. 17, 2019

Related U.S. Application Data
(60) Provisional application No. 62/691,102, filed on Jun. 28, 2018.

(51) Int. Cl. H01L 27/146; H01L 31/032; H01L 31/0392; H01L 29/24; H01L 29/786

(52) U.S. Cl. CPC H01L 27/14616; H01L 27/1461; H01L 27/14649; H01L 29/7869; H01L 31/0322; H01L 31/03928; H01L 29/24; H01L 27/14689

(57) ABSTRACT

Methods and apparatus form an image sensor pixel circuit on flexible and non-flexible substrates. At least one indium-gallium-zinc-oxide (IGZO) thin film transistor (TFT) is formed at a process temperature of approximately 400 degrees Celsius or less and at least one photodiode is formed on at least one of the at least one IGZO TFT. The at least one photodiode having an absorption layer formed, at least in part, by depositing a copper-indium-gallium-selenium (CIGS) material with a gallium mole fraction of approximately 35% to approximately 70% at a process temperature of less than or equal to approximately 400 degrees Celsius and doping the CIGS material with antimony at a process temperature of less than or equal to approximately 400 degrees Celsius.

### CROSS-REFERENCE TO RELATED APPLICATIONS

This application claims benefit of U.S. provisional patent application Ser. No. 62/691,102, filed Jun. 28, 2018 which is herein incorporated by reference in its entirety.

### FIELD

Embodiments of the present principles generally relate to semiconductor manufacturing.

### BACKGROUND

Image sensors capture light and transform the light into electrical signals that result in the creation of digital images. An image sensor has millions of picture elements or pixels arranged in an array of rows and columns. Each pixel has a pixel architecture that includes a photodiode and associated pixel circuitry to produce electrical signals when light impinges upon a particular pixel. The photodiode absorbs light and creates a charged condition. Pixel circuitry then converts the charge to a voltage to generate electrical signals. The electrical signals, in part, indicate the row and column of the pixel that is absorbing the light. In some pixel architectures, thin film transistors (TFT) with amorphous silicon are used in the associated pixel circuitry. The inventors have observed that the amorphous silicon TFTs require high process temperatures during manufacturing that substantially limit how and when the amorphous silicon TFTs can be used. High process temperatures of the amorphous silicon TFTs limit types of material that can be used with the amorphous silicon TFTs and reduce available thermal budgets for prior and subsequent semiconductor processes that incorporate the amorphous silicon TFTs.

Thus, the inventors have provided methods and apparatus for enhanced pixel circuitry for image sensor applications.

### SUMMARY

Methods and apparatus for enhanced pixel circuitry for image sensor applications.

In some embodiments, an apparatus for detecting an image comprises a photodiode with an absorption layer of copper-indium-gallium-selenium (CIGS) material with a gallium mole fraction of approximately 35% to approximately 70%, the CIGS material doped with antimony and a pixel circuit electrically interfacing with the photodiode and having at least one indium-gallium-zinc-oxide (IGZO) thin film transistor (TFT).

In some embodiments, the apparatus may further comprise wherein the CIGS material has a gallium mole fraction of approximately 57%, wherein the apparatus is formed on a flexible substrate, wherein the flexible substrate is a biometric substrate, wherein the absorption layer absorbs photons with wavelengths up to near infrared, wherein the CIGS material is doped with approximately 1.2 mol % to approximately 5 mol % antimony, wherein the CIGS material has sub-micron grain sizes, wherein the CIGS material absorbs wavelengths less than or equal to approximately 940 nm and is transparent to wavelengths greater than approximately 940 nm, wherein the CIGS material has a bandgap of approximately 1.31 eV, a pixel circuit electrically interfacing with the photodiode and having at least one IGZO TFT configured to dissipate a charge generated by the photodiode, a pixel circuit electrically interfacing with the photodiode and having at least one IGZO TFT configured to amplify a signal from the photodiode, and/or a pixel circuit electrically interfacing with the photodiode and having at least one IGZO TFT configured in a readout circuit of an image sensor.

In some embodiments, a method of producing an image sensor pixel circuit comprises forming at least one indium-gallium-zinc-oxide (IGZO) thin film transistor at a process temperature of approximately 400 degrees Celsius or less and forming at least one photodiode on at least one of the at least one IGZO transistor, the at least one photodiode having an absorption layer formed, at least in part, by depositing a copper-indium-gallium-selenium (CIGS) material with a gallium mole fraction of approximately 35% to approximately 70% at a process temperature of less than or equal to approximately 400 degrees Celsius such that a sub-micron grain size is achieved for the CIGS material and doping the CIGS material with antimony at a process temperature of less than or equal to approximately 400 degrees Celsius.

In some embodiments, the method further comprises forming the image sensor pixel circuit on a flexible substrate, wherein the flexible substrate is a biometric substrate, depositing a CIGS material with a gallium mole fraction of approximately 57%, wherein the absorption layer absorbs photons with wavelengths up to near infrared, doping the CIGS material with antimony at a process temperature of less than or equal to approximately 350 degrees Celsius and/or doping the CIGS material to approximately 1.2 mol % to approximately 5 mol % antimony.

In some embodiments, a method of producing an image sensor pixel circuit comprises forming at least one indium-gallium-zinc-oxide (IGZO) thin film transistor (TFT) at a process temperature of approximately 350 degrees Celsius or less and forming at least one photodiode on at least one of the at least one IGZO TFT, the at least one photodiode having an absorption layer formed, at least in part, by depositing a copper-indium-gallium-selenium (CIGS) material with a gallium mole fraction of approximately 57%, controlling a deposition temperature of the CIGS material to less than approximately 350 degrees Celsius to produce sub-micron grain size in the CIGS material during deposition, and doping the CIGS material with approximately 1.2 mol % to approximately 5 mol % antimony at a process temperature of less than or equal to approximately 350 degrees Celsius.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of producing a pixel circuit structure in accordance with some embodiments of the present principles.

FIG. 2 depicts a cross sectional view of a pixel circuit structure in accordance with some embodiments of the present principles.

FIG. 3 depicts pixel circuitry in accordance with some embodiments of the present principles.

FIG. 4 is another method of producing a pixel circuit structure in accordance with some embodiments of the present principles.

FIG. 5 is yet another method of producing a pixel circuit structure in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus of the present principles provide an optimized pixel architecture for image sensor applications. The pixel architecture includes a photodiode with an absorber layer of a copper-indium-gallium-selenium (CIGS) material and pixel circuitry with at least one indium-gallium-zinc-oxide (IGZO) thin film transistor (TFT). The CIGS material has a gallium mole fraction of approximately 35% to approximately 70% with reduced dark current (low noise) for use with near infrared (NIR) applications. The CIGS material is deposited using a low temperature process that yields sub-micron grain sizes to provide enhanced resolution capabilities. The CIGS material is doped with antimony (Sb) in a low temperature process to create high absorption through charge carrier modulation. Detailed information on the production of the CIGS material can be found in the co-pending U.S. provisional patent application Ser. No. 62/691,079, entitled METHODS AND APPARATUS FOR PRODUCING COPPER-INDIUM-GALLIUM-SELENIUM (CIGS) FILM. The IGZO TFT is produced using low temperatures making the IGZO TFT compatible with flexible substrates (e.g., polymers) and non-flexible substrates (e.g., glass). Other advantages of the IGZO TFT over an amorphous silicon TFT besides low manufacturing process temperatures include high field-effect mobility (>10 cm²/Vs), small S-factor (driven by low voltage), and high uniformity. The IGZO TFT also has low off-current which further reduces pixel circuit noise.

The unique combination of a photodiode with an absorber layer of CIGS material and an IGZO TFT advantageously produces a pixel architecture incorporating semiconductor devices with greater application flexibility due to the low processing temperatures. The use of biometric substrates (highly flexible, low melting temperature) become possible, beneficially allowing the creation of image sensors that can be applied to skin and other flexible surfaces and the like. Devices with biometric substrates (e.g., flexible substrates) can be used to measure biometrics such as, but not limited to, blood flow and skin conditions and the like. The combination provides a high quantum efficiency (QE) photo conductive film with low dark current and low read out noise for image sensor applications at NIR. IGZO material for TFT circuits on flexible substrates outperforms amorphous silicon due to the IGZO material's higher electron mobility. The higher electron mobility means the IGZO TFT requires less mass (smaller size) for the same conductivity as an amorphous silicon TFT. The smaller size of the IGZO TFT also enhances image sensor resolution by allowing higher pixel densities and also reduces power requirements for transistor operations. The CIGS material for image sensor applications provides enhanced performance due to the GIGS material's higher absorption at NIR than that of silicon. By using the CIGS material as an absorber layer in a photodiode and the IGZO material for the TFT circuitry, a high QE CIGS photodiode can be manufactured on a flexible substrate at a low temperature.

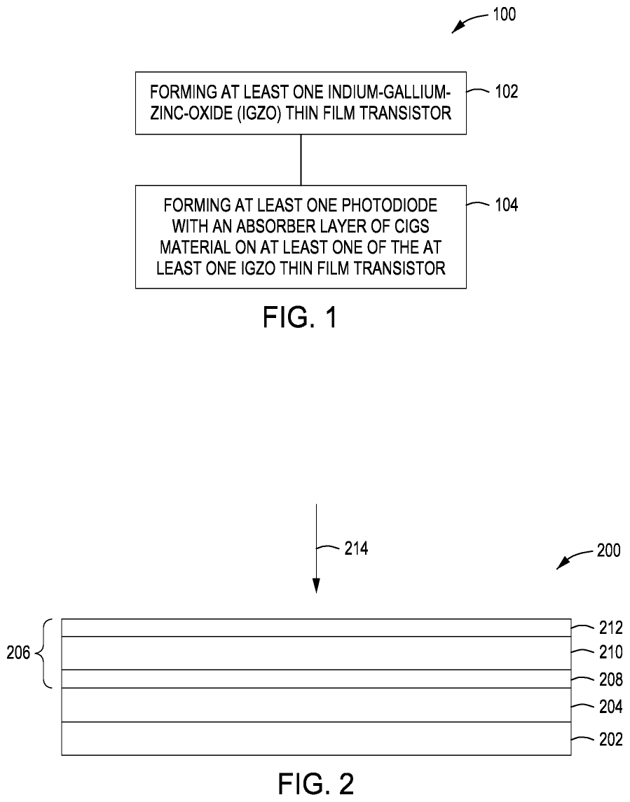

FIG. 1 is a method 100 of producing a pixel circuit structure in accordance with some embodiments. In block 102, at least one IGZO TFT 204 is formed on a substrate 202 as shown in FIG. 2. FIG. 2 depicts a cross sectional view of a pixel circuit structure 200 in accordance with some embodiments. In some embodiments, the substrate 202 may be a flexible substrate such as, but not limited to, a polymer substrate (e.g., plastic). In some embodiments, the substrate 202 may be a non-flexible substrate such as, but not limited to, a silicon substrate and the like. In some embodiments, the at least one IGZO TFT 204 may be formed using a low temperature process such as a temperature of less than or equal to approximately 400 degrees Celsius. In some embodiments, the at least one IGZO TFT 204 may be formed using a low temperatures process such as a temperature of less than or equal to approximately 350 degrees Celsius. The relationship of the composition of materials of the IGZO TFT is noted by InGaZnO₄. In some embodiments, the material composition may be In₂O₃+Ga₂O₃+2.ZnO.

In block 104 of FIG. 1, a photodiode 206 with an absorber layer 210 of CIGS material is formed on the at least one IGZO TFT 204. The photodiode 206 also includes a bottom electrode 208 and a top electrode 212 with the absorber layer 210 interposed in between. In some embodiments, a hole blocking layer (not shown) may be interposed between the top electrode and the absorber layer 210. The hole blocking layer may be comprised of Ga₂O₃ or ZnO and the like. In some embodiments, an n-type layer may be interposed between the hole blocker layer and the absorber layer 210. The n-type layer may include a Ga₂O₃:Sn layer or Zn(O,S) layer and the like. The relationship of the composition of materials of the GIGS material is noted by Cu(In₁₋ₓGaₓ)Se₂. In some embodiments, the CIGS material has a gallium mole fraction of approximately 35% to approximately 70% for reduced dark currents in NIR sensor applications. In some embodiments, the CIGS material has a gallium mole fraction of approximately 57%. In some embodiments, the CIGS material is deposited using a deposition temperature of approximately 400 degrees Celsius or less to create sub-micron grain sizes to enhance image sensor resolution. In some embodiments, the CIGS material is deposited using a deposition temperature of approximately 350 degrees Celsius or less. In some embodiments, the GIGS material is doped with antimony at a process temperature of 400 degrees Celsius or less to provide high absorption through charge carrier modulation. In some embodiments, the GIGS material is doped with antimony at a process temperature of 350 degrees Celsius or less. In some embodiments, the antimony doping is from approximately 1.2 mol % to approximately 5 mol %.

Another benefit of the IGZO material is that the IGZO material is optically transparent. The optical transparency is yet another advantage over amorphous silicon TFTs. The IGZO TFT may be produced on the substrate after the photodiode in a configuration above the photodiode with minimal impact on the operation of the photodiode. The transparency can also aid in configurations where backlighting is used (less backlighting is required and less power is required) with IGZO material. Another advantage of the IGZO TFT is the IGZO TFT's low leakage currents (yielding less noise).

When light 214 (FIG. 2) impinges on the pixel circuit structure 200, photons with enough energy are absorbed in the absorber layer 210, creating a charge condition with electrons at the top electrode 212 and holes at the bottom electrode 208. The charge condition produces a voltage potential which is then converted to electrical signals by the pixel circuitry (e.g., the at least one IGZO TFT 204, etc.) to transmit image information through a pixel access structure (e.g., row and column select) of the pixel. Reset circuitry may also be utilized to reset (zero) the charge condition on the photodiode 206 or an accompanying capacitor holding the charge. The pixel circuitry may also include an amplifying TFT to enhance the electrical signals for better signal performance and less noise.

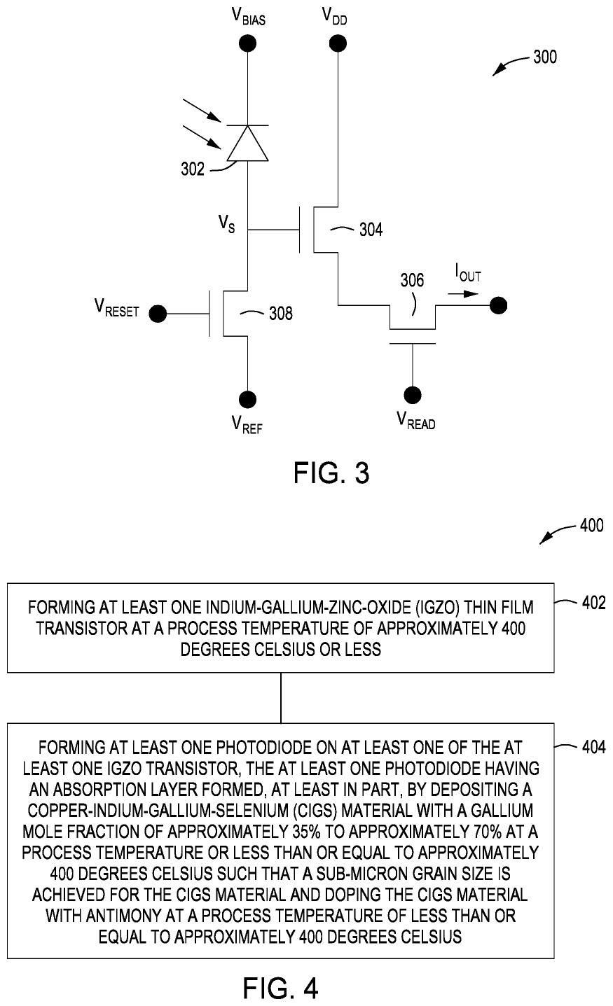

FIG. 3 depicts a pixel circuitry 300 in accordance with some embodiments. The pixel circuitry 300 includes a photodiode 302 produced in accordance with the present principles. The bottom electrode 208 (FIG. 2) is connected to a gate of an amplifying transistor 304. The source of the amplifying transistor 304 is connected to a drain of a read transistor 306 which can provide a readout current to a subsequent readout circuit (not shown). The bottom electrode 208 may also be connected to a drain of a reset transistor 308. The reset transistor 308 is used to remove charge buildup on the photodiode 302. In some embodiments, at least one of the transistors (304-308) may an IGZO TFT. In some embodiments, the readout circuit (not shown) may also have at least one IGZO TFT. When in a reset mode, the reset transistor 308 is ON and the read transistor 306 is OFF. A voltage V_{S} is set to V_{REF} which is greater than the threshold voltage of the amplifying transistor 304. When the pixel circuitry 300 is receiving light, the light induces a photocurrent in the photodiode 302. The light photons are converted into an electrical signal (induced charge). After the light is received, the read transistor 306 is turned ON and an output current lour flows into a readout circuit (not shown) to read the charge. In some embodiments, a capacitor (not shown) may be placed across the photodiode 302 to hold the charge. In some embodiments, other configurations of pixel circuitry may be used with the CIGS absorber layer photodiode and IGZO transistor combination produced per the present principles.

FIG. 4 is another method 400 of producing a pixel circuit structure in accordance with some embodiments. In block 402, at least one IGZO TFT is formed on a substrate at a process temperature of approximately 400 degrees Celsius or less. The relationship of the composition of materials of the IGZO TFT is noted by InGaZnO₄. In some embodiments, the material composition may be In₂O₃+Ga₂O₃+2.ZnO. In block 404 of FIG. 4, at least one photodiode with an absorber layer of CIGS material is formed on the at least one IGZO TFT. The absorption layer is formed, at least in part, by depositing a copper-indium-gallium-selenium (CIGS) material with a gallium mole fraction of approximately 35% to approximately 70% at a process temperature of less than or equal to approximately 400 degrees Celsius such that a sub-micron grain size is achieved for the CIGS material and doping the CIGS material with antimony at a process temperature of less than or equal to approximately 400 degrees Celsius.

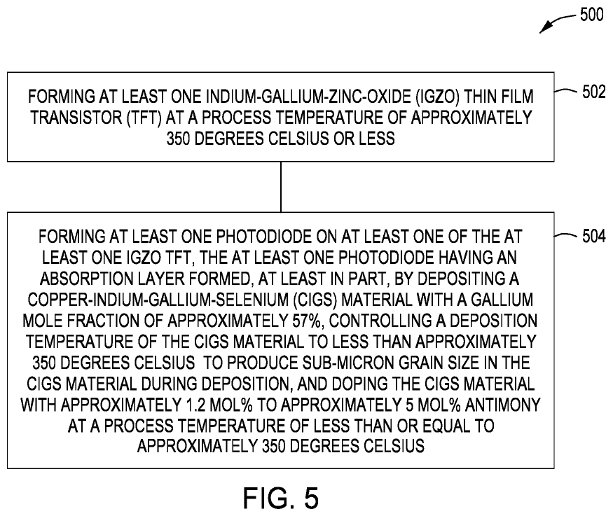

FIG. 5 is yet another method 500 of producing a pixel circuit structure in accordance with some embodiments. In block 502, at least one IGZO TFT is formed on a substrate at a process temperature of approximately 350 degrees Celsius or less. The relationship of the composition of materials of the IGZO TFT is noted by InGaZnO₄. In some embodiments, the material composition may be In₂O₃+Ga₂O₃+2.ZnO. In block 504 of FIG. 5, at least one photodiode with an absorber layer of CIGS material is formed on the at least one IGZO TFT. The absorption layer is formed, at least in part, by depositing a copper-indium-gallium-selenium (CIGS) material with a gallium mole fraction of approximately 57% at a process temperature of less than or equal to approximately 350 degrees Celsius to produce sub-micron grain size in the CIGS material during deposition, and doping the CIGS material with approximately 1.2 MOL % to approximately 5 MOL % antimony at a process temperature of less than or equal to approximately 350 degrees Celsius.

While the foregoing is directed to embodiments of the present principles, other and further embodiments of the principles may be devised without departing from the basic scope thereof.

1. An apparatus for detecting an image, comprising:
a photodiode with an absorption layer of copper-indium-gallium-selenium (CIGS) material with a gallium mole fraction of approximately 35% to approximately 70%, the CIGS material doped with antimony; and
a pixel circuit electrically interfacing with the photodiode and having at least one indium-gallium-zinc-oxide (IGZO) thin film transistor (TFT).

2. The apparatus of claim 1, wherein the CIGS material has a gallium mole fraction of approximately 57%.

3. The apparatus of claim 1, wherein the apparatus is formed on a flexible substrate.

4. The apparatus of claim 3, wherein the flexible substrate is a biometric substrate.

5. The apparatus of claim 1, wherein the absorption layer absorbs photons with wavelengths up to near infrared.

6. The apparatus of claim 1, wherein the CIGS material is doped with approximately 1.2 mol % to approximately 5 mol % antimony.

7. The apparatus of claim 1, wherein the CIGS material has sub-micron grain sizes.

8. The apparatus of claim 1, wherein the CIGS material absorbs wavelengths less than or equal to approximately 940 nm and is transparent to wavelengths greater than approximately 940 nm.

9. The apparatus of claim 1, wherein the CIGS material has a bandgap of approximately 1.31 eV.

10. The apparatus of claim 1, further comprising:
a pixel circuit electrically interfacing with the photodiode and having at least one IGZO TFT configured to dissipate a charge generated by the photodiode.

11. The apparatus of claim 1, further comprising:
a pixel circuit electrically interfacing with the photodiode and having at least one IGZO TFT configured to amplify a signal from the photodiode.

12. The apparatus of claim 1, further comprising:
a pixel circuit electrically interfacing with the photodiode and having at least one IGZO TFT configured in a readout circuit of an image sensor.

13. A method of producing an image sensor pixel circuit, comprising:
forming at least one indium-gallium-zinc-oxide (IGZO) thin film transistor at a process temperature of approximately 400 degrees Celsius or less; and
forming at least one photodiode on at least one of the at least one IGZO transistor, the at least one photodiode having an absorption layer formed, at least in part, by:
depositing a copper-indium-gallium-selenium (CIGS) material with a gallium mole fraction of approximately 35% to approximately 70% at a process temperature of less than or equal to approximately 400 degrees Celsius such that a sub-micron grain size is achieved for the CIGS material; and
doping the CIGS material with antimony at a process temperature of less than or equal to approximately 400 degrees Celsius.

14. The method of claim 13, further comprising:
forming the image sensor pixel circuit on a flexible substrate.

15. The method of claim 14, wherein the flexible substrate is a biometric substrate.

16. The method of claim 13, further comprising:
depositing a CIGS material with a gallium mole fraction of approximately 57%.

17. The method of claim 13, wherein the absorption layer absorbs photons with wavelengths up to near infrared.

18. The method of claim 13, further comprising:
doping the CIGS material with antimony at a process temperature of less than or equal to approximately 350 degrees Celsius.

19. The method of claim 13, further comprising:
doping the CIGS material to approximately 1.2 mol % to approximately 5 mol % antimony.

20. A method of producing an image sensor pixel circuit, comprising:
forming at least one indium-gallium-zinc-oxide (IGZO) thin film transistor (TFT) at a process temperature of approximately 350 degrees Celsius or less; and
forming at least one photodiode on at least one of the at least one IGZO TFT, the at least one photodiode having an absorption layer formed, at least in part, by:
depositing a copper-indium-gallium-selenium (CIGS) material with a gallium mole fraction of approximately 57%;
controlling a deposition temperature of the CIGS material to less than approximately 350 degrees Celsius to produce sub-micron grain size in the CIGS material during deposition; and
doping the CIGS material with approximately 1.2 mol % to approximately 5 mol % antimony at a process temperature of less than or equal to approximately 350 degrees Celsius.
